(19) United States
(12) Patent Application Publication
(10) Pub. No.: US 2020/0103468 A1
(43) Pub. Date: Apr. 2, 2020

(54) SOC ESTIMATION APPARATUS

(71) Applicant: DENSO TEN Limited, Kobe-shi (JP)

(72) Inventors: Takahiro WATANABE, Kobe-shi (JP); Masato HISANAGA, Kobe-shi (JP); Takashi SHIMOMACHI, Sakai-shi (JP)

(73) Assignee: DENSO TEN Limited, Kobe-shi (JP)

(21) Appl. No.: 16/542,348

(22) Filed: Aug. 16, 2019

(30) Foreign Application Priority Data
Sep. 27, 2018 (JP) 2018-181922
Jun. 27, 2019 (JP) 2019-119875

(51) Int. Cl. G01R 31/3842; H02J 7/00; G01R 31/374

(52) U.S. Cl. CPC G01R 31/3842; G01R 31/374; H02J 7/0021

(57) ABSTRACT

A state of charge estimation apparatus that estimates a state of charge of a secondary battery includes a processor and associated memory configured to: obtain a voltage measurement value, a current measurement value, and a temperature measurement value of the second battery; calculate a state of charge estimation value of the secondary battery based on the current measurement value; determine whether or not the voltage measurement value of the secondary battery has reached a predetermined voltage threshold during charge or discharge of the secondary battery; and in a case where the voltage measurement value of the secondary battery is determined to have reached the voltage threshold, correct the state of charge estimation value based on the current measurement value and the temperature measurement value that are obtained at a correction time point at which the voltage measurement value of the secondary battery has reached the voltage threshold.

### BACKGROUND OF THE INVENTION

### Field of the Invention

The invention relates to an SOC estimation apparatus that estimates a state of charge of a secondary battery.

### Description of the Background Art

An electric powered vehicle, such as hybrid vehicle and electric vehicle, includes a power source that supplies electricity to a motor as a power supply. Mainly, a secondary battery is used as the power source for the electric powered vehicles. The secondary battery supplies power to the motor by discharge, and stores electric power regenerated by the motor.

For stable supply of the power from the secondary battery to the motor, the electric powered vehicles include a state of charge (SOC) estimation apparatus that estimates an SOC of the secondary battery. The SOC is equivalent to a charging rate of the secondary battery. The SOC estimation apparatus obtains a current measurement value from a sensor that measures electric current running through the secondary battery, and then integrates the obtained current measurement values. The integration of the current measurement values is used as an SOC estimation value. The method of estimating the SOC by integrating current measurement values is called coulomb counting method.

However, the current measurement values include errors so that the errors of the current measurement values are also integrated and included in the SOC estimation value. Thus, the coulomb counting method has a problem with a decrease in accuracy of the SOC estimation value with time.

In order to prevent the decrease in the accuracy of the SOC estimation value, conventionally, there has been an SOC estimation apparatus for the secondary battery that estimates an open voltage of the secondary battery during charge or discharge of the secondary battery, and then estimates the SOC of the secondary battery based on the estimated open voltage. In a case of the conventional SOC estimation apparatus, while the discharge of the secondary battery continues, an internal resistance reference value is not updated. Thus, in a case where there is a great difference between an open voltage measured when discharge is started and an open voltage measured when an SOC is estimated, the accuracy in the SOC estimation may be decreased.

### SUMMARY OF THE INVENTION

According to one aspect of the invention, a state of charge estimation apparatus estimates a state of charge of a secondary battery. The state of charge estimation apparatus includes a processor and associated memory configured to: obtain a voltage measurement value, a current measurement value, and a temperature measurement value of the second battery; calculate a state of charge estimation value of the secondary battery based on the current measurement value; determine whether or not the voltage measurement value of the secondary battery has reached a predetermined voltage threshold during charge or discharge of the secondary battery; and in a case where the voltage measurement value of the secondary battery is determined to have reached the voltage threshold, correct the state of charge estimation value based on the current measurement value and the temperature measurement value that are obtained at a correction time point at which the voltage measurement value of the secondary battery has reached the voltage threshold.

Thus, the SOC estimation value is corrected based on the temperature of the secondary battery and the current flowing through the secondary battery measured at the time point at which the voltage measurement value has reached the voltage threshold. Since a parameter that has measured before discharge or charge of the secondary battery is not used for the correction of the SOC estimation value, even in a case where discharge or charge of the secondary battery continues, accuracy of the SOC estimation value can be improved.

According to another aspect of the invention, the processor is further configured to: determine whether or not an operating point of the secondary battery is within a first region that is defined based on current flowing through the secondary battery and temperature of the secondary battery, the operating point of the secondary battery being defined by the current measurement value and the temperature measurement value that are obtained at the correction time point; and in a case where the operating point is determined to be within the first region, correct the state of charge estimation value by use of a correction value corresponding to the first region.

In the case where the operating point is within the first region, the SOC estimation value is corrected. In a case where correcting the SOC estimation value is inappropriate, the corrector does not correct the SOC estimation value. Thus, it is possible to prevent accuracy of the SOC estimation value from decreasing by correcting the SOC estimation value.

Thus, an object of the invention is to provide an SOC estimation apparatus that improves accuracy of an SOC estimation if discharge or charge of a secondary battery continues.

These and other objects, features, aspects and advantages of the invention will become more apparent from the following detailed description of the invention when taken in conjunction with the accompanying drawings.

### BRIEF DESCRIPTION OF THE DRAWINGS

FIG. 1 illustrates a functional block diagram indicative of a configuration of a vehicle-mounted system that uses an SOC estimation apparatus of an embodiment of the present application;

FIG. 2 illustrates a functional block diagram indicative of a configuration of the SOC estimation apparatus shown in FIG. 1;

FIG. 3 illustrates a functional block diagram indicative of a configuration of a corrector shown in FIG. 2;

FIG. 4 is a flowchart showing an operation of the SOC estimation apparatus shown in FIG. 1;

FIG. 5 is a flowchart of the SOC estimation value correction process shown in FIG. 4;

FIG. 6 illustrates an example of correction region data that is used in a case where a voltage measurement value has reached a lower limit value;

FIG. 7 illustrates an example of a correction value table shown in FIG. 2;

FIG. 8 illustrates an example of correction region data that is used in a case where the voltage measurement value has reached an upper limit value; and

FIG. 9 illustrates an example of a configuration of a CPU bus.

### DESCRIPTION OF THE EMBODIMENTS

An embodiment of this invention will be described below in detail with reference to the drawings. The same numeral references will be given to same or equal part/portions to previously described ones, and explanation of the same or equal part/portions will not be repeated.

[1. Configuration]

[1.1. Configuration of Vehicle-Mounted System 100]

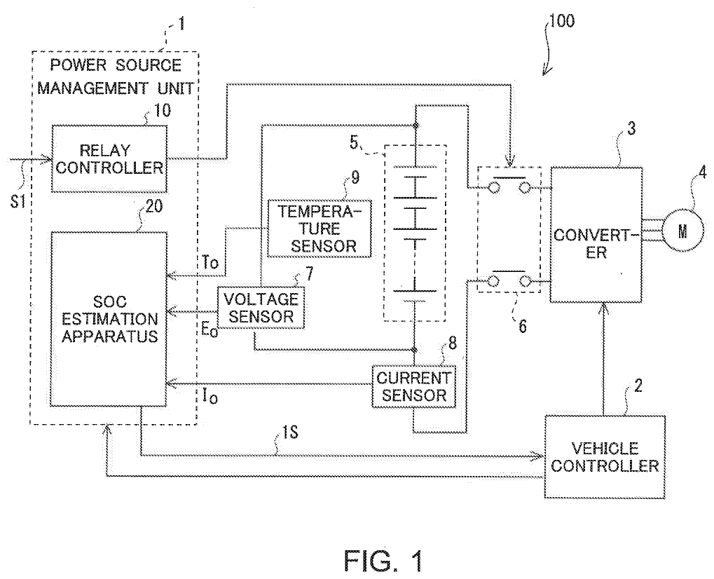

FIG. 1 is a functional block diagram indicative of a vehicle-mounted system 100 that uses an SOC estimation apparatus 20 of the embodiment. As shown in FIG. 1, the vehicle-mounted system 100 is installed in, for example, a hybrid electric vehicle (HEV), an electric vehicle (EV), etc., not illustrated. The vehicle-mounted system 100 supplies electricity from a secondary battery 5 to a motor 4, and supplies electricity regenerated by the motor 4 to the secondary battery 5. The motor 4 is a driving source of a vehicle. The secondary battery 5 is a power source of the vehicle.

The vehicle-mounted system 100 includes a power source management unit 1, a vehicle controller 2, a converter 3, the motor 4, the secondary battery 5, a relay 6, a voltage sensor 7, a current sensor 8, and a temperature sensor 9.

The power source management unit 1 connects the converter 3 to the secondary battery 5, depending on a state of an ignition switch (not illustrated) in the vehicle. The power source management unit 1 outputs a state of charge (SOC) value 1S of the secondary battery 5. The SOC value 1S is, for example, a charge rate of the secondary battery 5. The SOC value 1S may be a remaining capacity of the secondary battery 5.

The vehicle controller 2 performs a charge control and a discharge control for the secondary battery 5 based on the SOC value 1S received from the power source management unit 1. When the vehicle controller 2 performs the discharge control, the converter 3 converts direct current supplied from the secondary battery 5 to three-phase alternating current, based on an instruction from the vehicle controller 2. The motor 4 is powered by the converted three-phase alternating current. When the vehicle controller 2 performs the charge control, the converter 3 converts, to the direct current, the three-phase alternating current supplied by the motor 4, based on an instruction from the vehicle controller 2. When working as a regeneration brake, the motor 4 generates the three-phase alternating current, and supplies the generated three-phase alternating current to the converter 3.

The secondary battery 5 is, for example, an assembled battery, and includes a plurality of cell stacks connected in series. Each of the plurality of cell stacks includes a plurality of cells connected in series. A lithium-ion secondary battery and a nickel hydrogen battery are some among the plurality of cells.

The relay 6 is turned on and off by the power source management unit 1. The secondary battery 5 is electrically connected to the converter 3 by turning on the relay 6. The electrical connection between the converter 3 and the secondary battery 5 is disconnected by turning off the relay 6.

The voltage sensor 7 measures closed circuit voltage (CCV) of the secondary battery 5, and obtains a voltage measurement value Eo as a measured result. The voltage sensor 7 outputs the obtained voltage measurement value Eo to the SOC estimation apparatus 20.

The current sensor 8 measures current flowing through the secondary battery 5, and obtaines a current measurement value Io as a measured result. The current sensor 8 outputs the obtained current measurement value Io to the SOC estimation apparatus 20.

The temperature sensor 9 measures temperature of the secondary battery 5, and obtains a temperature measurement value To as a measured result. The temperature sensor 9 outputs the obtained temperature measurement value To to the SOC estimation apparatus 20. The temperature of the secondary battery 5 is, for example, surface temperature of each of the plurality of cell stacks. The temperature sensor 9 may detect the surface temperature of a portion of the plurality of cell stacks.

[1.2. Configuration of the Power Source Management Unit 1]

The power source management unit 1 includes a relay controller 10 and the SOC estimation apparatus 20.

The relay controller 10 controls On and Off of the relay 6 based on an ignition signal S1 from the ignition switch. More specifically, when the ignition signal S1 indicates that the ignition switch is On, the relay controller 10 turns on the relay 6, and electrically connects the secondary battery 5 to the converter 3. When the ignition signal S1 indicates that the ignition switch is Off, the relay controller 10 turns off the relay 6, and disconnects the electrical connection between the converter 3 and the secondary battery 5.

The SOC estimation apparatus 20 estimates an SOC of the secondary battery 5. More specifically, the SOC estimation apparatus 20 receives the current measurement value Io from the current sensor 8, and then estimates the SOC of the secondary battery 5 based on the received current measurement value Io. The SOC estimation apparatus 20 outputs the SOC value 1S to the vehicle controller 2 as an SOC estimation result. When the voltage measurement value Eo reaches a predetermined voltage threshold, the SOC estimation apparatus 20 corrects the estimated SOC based on the current measurement value Io and the temperature measurement value To.

[1.3. Configuration of the SOC Estimation Apparatus 20]

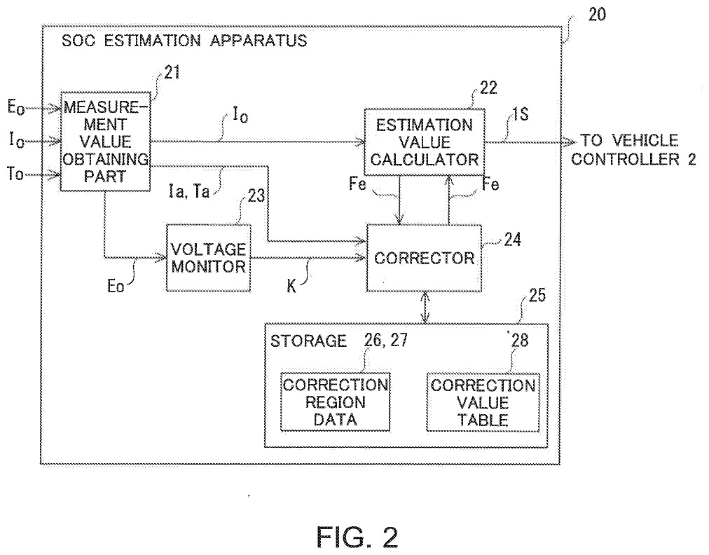

FIG. 2 illustrates a functional block diagram showing a configuration of the SOC estimation apparatus 20 shown in FIG. 1. As shown in FIG. 2, the SOC estimation apparatus 20 includes a measurement value obtaining part 21, an estimation value calculator 22, a voltage monitor 23, a corrector 24, and a storage 25.

The measurement value obtaining part 21 obtains the voltage measurement value Eo from the voltage sensor 7, the current measurement value Io from the current sensor 8, and the temperature measurement value To from the temperature sensor 9. Frequencies to obtain the voltage measurement value Eo, the current measurement value Io, and the temperature measurement value To may be same or different from one another. Timing of obtaining the voltage measurement value Eo, the current measurement value Io, and the temperature measurement value To may be same or different from one another.

The measurement value obtaining part 21 outputs the obtained current measurement value Io to the estimation value calculator 22. The measurement value obtaining part 21 outputs the obtained voltage measurement value Eo to the voltage monitor 23. The measurement value obtaining part 21 outputs a current measurement value Ia and a temperature measurement value Ta obtained at a correction time point to the corrector 24. The correction time point will be described later.

The estimation value calculator 22 calculates an SOC estimation value Fe of the secondary battery 5 based on the current measurement value Io received from the measurement value obtaining part 21. The SOC estimation value Fe is calculated whenever the measurement value obtaining part 21 obtains the current measurement value Io. Details of the estimation value calculator 22 will be described later.

In a case where the calculated SOC estimation value Fe has not been corrected by the corrector 24, the estimation value calculator 22 outputs, as the SOC value 1S, the calculated SOC estimation value Fe to the vehicle controller 2. When receiving the corrected SOC estimation value Fe from the corrector 24, the estimation value calculator 22 outputs, as the SOC value 1S, the corrected SOC estimation value Fe to the vehicle controller 2.

During constant current charge or discharge of the secondary battery 5, the voltage monitor 23 determines whether the voltage measurement value Eo has reached the predetermined voltage threshold. The voltage threshold includes an upper limit value and a lower limit value. The upper limit value is a charge upper limit voltage of the secondary battery 5. The lower limit value is a discharge final voltage of the secondary battery 5. While the secondary battery 5 is being charged, the upper limit value is used as the voltage threshold. While the secondary battery 5 is being discharged, the lower limit value is used as the voltage threshold. The voltage monitor 23 outputs, to the corrector 24, a determination result K that indicates whether or not the voltage measurement value Eo has reached the voltage threshold.

In a case where the voltage monitor 23 determines that the voltage measurement value Eo has reached the voltage threshold, the corrector 24 determines, as the correction time point, a time point at which the voltage measurement value Eo has reached the voltage threshold. The corrector 24 obtains the current measurement value Ia and the temperature measurement value Ta obtained at the correction time point from amongst the current measurement values Io and the temperature measurement values To obtained by the measurement value obtaining part 21. The corrector 24 corrects the SOC estimation value Fe based on the current measurement value Ia and the temperature measurement value Ta obtained. Details of the corrector 24 will be described later.

The storage 25 is a nonvolatile memory, such as a read only memory (ROM) and a flash memory. The storage 25 stores correction region data 26 and 27, and a correction value table 28.

The correction region data 26 and 27 are used when the corrector 24 determines whether the SOC estimation value Fe should be corrected. The correction region data 26 is used when the voltage measurement value Eo has reached the lower limit value. The correction region data 27 is used when the voltage measurement value Eo has reached the upper limit value. The correction value table 28 is used when the corrector 24 determines a correction value of the SOC estimation value Fe. Details of the correction region data 26 and 27, and the correction value table 28 will be described later.

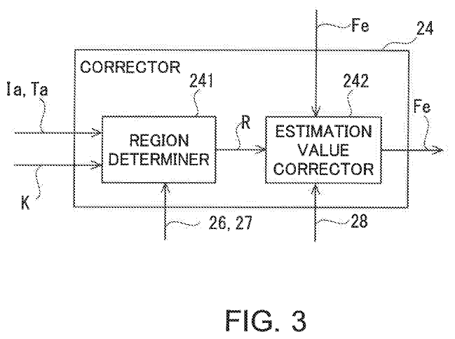

FIG. 3 illustrates a functional block diagram indicative of a configuration of the corrector 24. As shown in FIG. 3, the corrector 24 includes a region determiner 241 and an estimation value corrector 242.

The region determiner 241 receives the determination result K from the voltage monitor 23. In a case where the determination result K indicates that the voltage measurement value Eo has reached the voltage threshold, the region determiner 241 obtains, from the measurement value obtaining part 21, the current measurement value Ia and the temperature measurement value Ta obtained at the correction time point. The region determiner 241 determines whether or not an operating point of the secondary battery 5 is within a correction region. The operating point of the secondary battery 5 is determined by the obtained current measurement value Ia and the obtained temperature measurement value Ta. The correction region is stored in the correction region data 26 or the correction region data 27. The region determiner 241 outputs, to the estimation value corrector 242, a position determination result R that indicates whether or not the operating point of the secondary battery 5 is within the correction region.

In a case where the position determination result R indicates that the operating point is within the correction region, the estimation value corrector 242 corrects the SOC estimation value Fe, using the correction value table 28. The correction regions are associated with the correction values of the SOC estimation value Fe in the correction value table 28.

[2. Operation of the SOC Estimation Apparatus 20]

[2.1. Calculation of SOC Estimation Value]

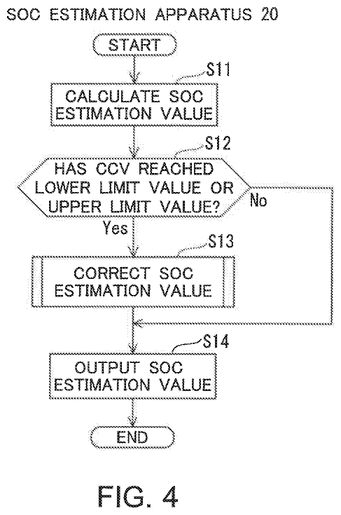

FIG. 4 is a flowchart showing an operation of the SOC estimation apparatus 20 shown in FIG. 1. During the constant current charge or discharge of the secondary battery 5, the SOC estimation apparatus 20 repeats a process shown in FIG. 4. More specifically, the process shown in FIG. 4 is performed every time at which the measurement value obtaining part 21 newly obtains the current measurement value Io.

Upon newly obtaining the current measurement value Io, the measurement value obtaining part 21 outputs the newly obtained current measurement value Io to the estimation value calculator 22. The estimation value calculator 22 calculates the SOC estimation value Fe based on the current measurement value Io received from the measurement value obtaining part 21 and on the SOC estimation value Fe that was calculated last time (a step S11).

For example, the SOC estimation value Fe is calculated by a coulomb counting method. The estimation value calculator 22 adds the current measurement value Io obtained at a time point t by the measurement value obtaining part 21 to the SOC estimation value Fe at a time point t−1 to derive the SOC estimation value Fe at the time point t. The time point t−1 is a time point at which the measurement value obtaining part 21 obtained the current measurement value Io immediately before the time point t. The SOC estimation value Fe is an integrated value of the current measurement value Io obtained by the measurement value obtaining part 21. In other words, the estimation value calculator 22 derives the SOC estimation value Fe by integrating current flowing through the secondary battery 5 over time. The derived SOC estimation value Fe is output to the estimation value corrector 242.

Upon newly obtaining the voltage measurement value Eo, the measurement value obtaining part 21 outputs the obtained voltage measurement value Eo to the voltage monitor 23. The voltage monitor 23 determines whether or not the voltage measurement value Eo received from the measurement value obtaining part 21 has reached the lower limit value or the upper limit value (a step S12). Since the secondary battery 5 is charging or discharging with the constant current, the voltage measurement value Eo is a CCV of the secondary battery 5. In other words, the voltage monitor 23 determines whether or not the CCV of the secondary battery 5 has reached the voltage threshold in the step S12.

The lower limit value is the discharge final voltage of the secondary battery 5. The upper limit value is the charging upper limit voltage of the secondary battery 5. In the step S12, during the constant current discharge of the secondary battery 5, the voltage monitor 23 determines whether or not the voltage measurement value Eo has reached the lower limit value. During the constant current charge of the secondary battery 5, the voltage monitor 23 determines whether or not the voltage measurement value Eo has reached the upper limit value.

In a case where the voltage measurement value Eo has not reached the lower limit value or the upper limit value (No in the step S 12), the voltage monitor 23 outputs, to the estimation value calculator 22 and the corrector 24, the determination result K indicating that the voltage measurement value Eo has not reached the lower limit value or the upper limit value. In this case, the estimation value corrector 242 does not correct the SOC estimation value Fe. The estimation value calculator 22 outputs the SOC estimation value Fe calculated in the step S11, as the SOC value 1S (a step S14).

In a case where the voltage measurement value Eo has reached the lower limit value or the upper limit value (Yes in the step S12), the voltage monitor 23 outputs, to the corrector 24, the determination result K indicating that the voltage measurement value Eo has reached the voltage threshold. The corrector 24 performs an SOC estimation value correction process (a step S13), described later, to correct the SOC estimation value Fe.

The estimation value calculator 22 obtains the corrected SOC estimation value Fe from the estimation value corrector 242, and then outputs the corrected SOC estimation value Fe as the SOC value 1S (a step S14). As a result of the SOC estimation value correction process, there is a case in which the SOC estimation value Fe is not corrected (the step S13). In this case, the estimation value calculator 22 outputs the SOC estimation value Fe calculated in the step S11, as the SOC value 1S (the step S14).

[2.2. SOC Estimation Value Correction Process (Step S13)]

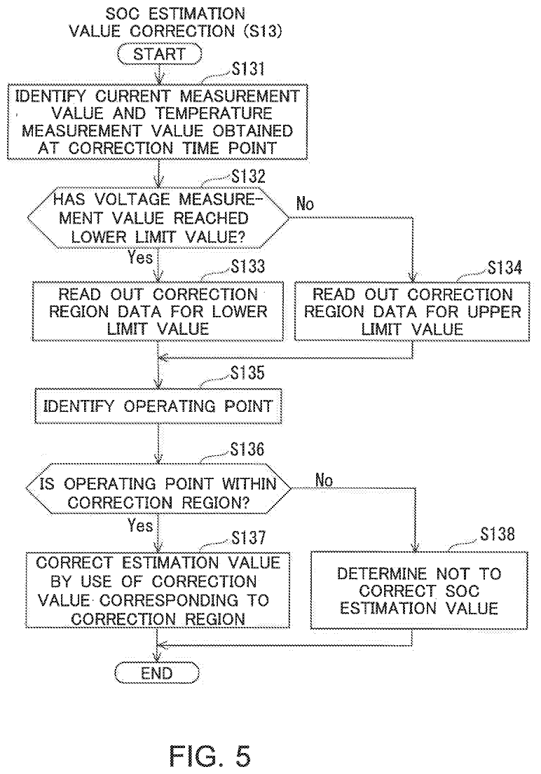

FIG. 5 is a flowchart of the SOC estimation value correction process (the step S13) shown in FIG. 4. With reference to FIG. 5, the step S13 will be described in detail, taking the case in which the voltage measurement value Eo has reached the lower limit value and the case in which the voltage measurement value Eo has reached the upper limit value separately as examples.

(Case in which the Voltage Measurement Value Eo has Reached the Lower Limit Value)

The region determiner 241 receives the determination result K from the voltage monitor 23. In a case where the determination result K indicates that the voltage measurement value Eo has reached the lower limit value (the discharge final voltage), the region determiner 241 determines, as the correction time point, a time point at which the voltage measurement value Eo has reached the lower limit value. The region determiner 241 identifies the current measurement value Ia and the temperature measurement value Ta obtained at the correction time point (a step S131).

More specifically, the region determiner 241 identifies, as the current measurement value Ia obtained at the correction time point, the current measurement value Io at a time point closest to the correction time point from among the current measurement values Io obtained by the measurement value obtaining part 21. The corrector 24 identifies, as the temperature measurement value Ta obtained at the correction time point, the temperature measurement value To at a time point closest to the correction time point from among the temperature measurement values To obtained by the measurement value obtaining part 21.

The current measurement value Ia may be the current measurement value Io obtained at a time point before or after the correction time point. The temperature measurement value Ta may also be the temperature measurement value Ta obtained at a time point before or after the correction time point.

Since the voltage measurement value Eo has reached the lower limit value (Yes in a step S132), the region determiner 241 reads out the correction region data 26 from the storage 25 (a step S133). The region determiner 241 identifies the operating point of the secondary battery 5 based on the current measurement value Ia and the temperature measurement value Ta at the correction time point (a step S135).

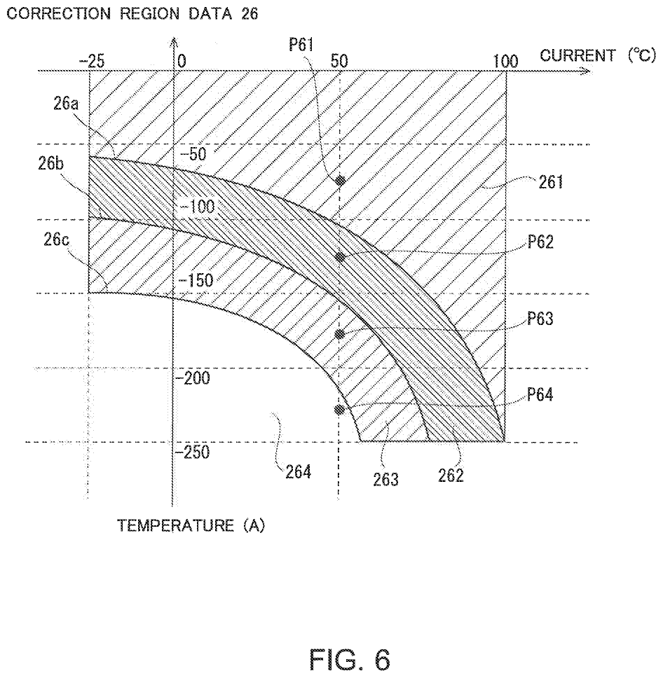

FIG. 6 illustrates an example of the correction region data 26 for the lower limit value. The correction region data 26 in FIG. 6 illustrates a relationship between a temperature of the secondary battery 5 and an ampacity current of the secondary battery 5 in the case where the voltage measurement value Eo has reached the discharge final voltage. The ampacity current of the secondary battery 5 is a current that can flow through the secondary battery 5 in the case where the voltage measurement value Eo has reached the discharge final voltage. Points P61 to P64 are examples of the operating point of the secondary battery 5 so that those points are not included in the correction region data 26.

The operating point of the secondary battery 5 identified in the step S135 should be located in a 2-dimensional coordinate having temperature of the secondary battery 5 on a horizontal axis and current flowing through the secondary battery 5 on a vertical axis, as shown in FIG. 6. For example, in a case where the temperature measurement value Ta is 50 degrees Celsius and the current measurement value Ia is −75 A, the operating point of the secondary battery 5 is the point P61. In a case where the temperature measurement value Ta is 50 degrees Celsius and the current measurement value Ia is −125 A, the operating point of the secondary battery 5 is the point P62. In a case where the temperature measurement value Ta is 50 degrees Celsius and the current measurement value Ia is −175 A, the operating point of the secondary battery 5 is the point P63. In a case where the temperature measurement value Ta is 50 degrees Celsius and the current measurement value Ia is −225 A, the operating point of the secondary battery 5 is the point P64.

As shown in FIG. 5, the region determiner 241 determines whether or not the operating point identified in the step S135 is within the correction region set in the correction region data 26 (a step S136). In a case where the operating point of the secondary battery 5 is within the correction region (Yes in the step S136), a step S137 is performed. In a case where the operating point is outside the correction region (No in the step S136), the process in a step S138 is performed.

As shown in FIG. 6, the correction region data 26 includes correction regions 261-263 and a non-correction region 264. The correction regions 261-263 are defined in a range of the temperature of the secondary battery 5 from −25 degrees Celsius to 100 degrees Celsius, and in a range of the current of the secondary battery 5 from −250 A to 0 A.

The correction region 261 is a region in which a true SOC (SOC that can be obtained on an assumption that there is no error) of the secondary battery 5 is 0% when the voltage measurement value Eo has reached the discharge final voltage. The correction region 262 is a region in which the true SOC of the secondary battery 5 is 1% when the voltage measurement value Eo has reached the discharge final voltage. The correction region 263 is a region in which the true SOC of the secondary battery 5 is 2% when the voltage measurement value Eo has reached the discharge final voltage. The non-correction region 264 is a region outside the correction regions 261-263 in the 2-dimensional coordinate shown in FIG. 6. A method of determining the correction regions 261-263 will be described later.

For example, when the operating point of the secondary battery 5 is the point P61, the region determiner 241 determines that the identified operating point is within the correction region 261 (Yes in the step S136). The region determiner 241 outputs, to the estimation value corrector 242, the position determination result R indicating that the operating point of the secondary battery 5 is within the correction region 261.

The step S137 will be described. Upon receiving, from the region determiner 241, the position determination result R indicating that the operating point of the secondary battery 5 is within the correction range, the estimation value corrector 242 corrects the SOC estimation value Fe by use of the correction value corresponding to the correction region indicated by the position determination result R (the step S137). More specifically, with reference to the correction value table 28, the estimation value corrector 242 determines the correction value corresponding to the correction region indicated by the position determination result R. The estimation value corrector 242 replaces the SOC estimation value Fe received from the estimation value calculator 22 with the determined correction value. Thus, the SOC estimation value Fe is corrected.

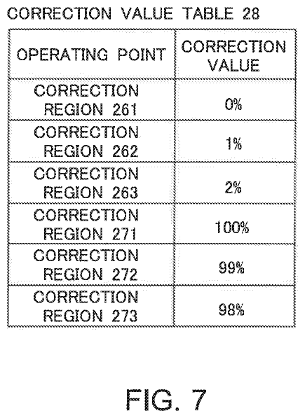

FIG. 7 illustrates an example of the correction value table 28. As shown in FIG. 7, in the correction value table 28, each of the correction regions 261-263 is associated with a correction value. The correction value (SOC) corresponding to the correction region 261 is 0%. The correction value corresponding to the correction region 262 is 1%. The correction value corresponding to the correction region 263 is 2%. Correction regions 271-273 are used in the case where the voltage measurement value Eo has reached the upper limit value. The correction regions 271-273 will be described later.

For example, in a case where the operating point of the secondary battery 5 is the point P61, as shown in FIG. 6, the operating point of the secondary battery 5 is within the correction region 261. The estimation value corrector 242 receives the position determination result R indicative of the correction region 261. The estimation value corrector 242 determines the correction value corresponding to the correction region 261 with reference to the correction value table 28. More specifically, the estimation value corrector 242 determines 0% as the correction value. Thus, the SOC estimation value Fe is corrected to 0%. The estimation value corrector 242 outputs the corrected SOC estimation value Fe to the estimation value calculator 22.

The step S138 will be described. In the case where the operating point identified in the step S135 is within the non-correction region 264 (No in the step S136), the region determiner 241 outputs, to the estimation value corrector 242, the position determination result R indicative of the non-correction region 264. In this case, the estimation value corrector 242 determines not to correct the SOC estimation value Fe (the step S138). The estimation value corrector 242 notifies the estimation value calculator 22 of a determination made in the step S138.

The method of determining the correction regions 261-263 will be described below. As shown in FIG. 6, the correction region 261 is a region between a boundary 26a and the horizontal axis. The correction region 262 is a region between the boundary 26a and a boundary 26b. The correction region 263 is a region between the boundary 26b and a boundary 26c. If the boundaries 26a-26c are identified, the correction regions 261-263 are determined.

The boundaries 26a-26c are curves that show the relationship between the temperature of the secondary battery 5 and the ampacity current of the secondary battery 5, and those curves are plotted based on the true SOC of the secondary battery 5 when the voltage measurement value Eo has reached the discharge final voltage.

The boundary 26a shows a relationship between the temperature of the secondary battery 5 and the ampacity current of the secondary battery 5 when the true SOC of the secondary battery 5 is 0%. The boundary 26b shows a relationship between the temperature of the secondary battery 5 and the ampacity current of the secondary battery 5 when the true SOC of the secondary battery 5 is 1%. The boundary 26c shows a relationship between the temperature of the secondary battery 5 and the ampacity current of the secondary battery 5 when the true SOC of the secondary battery 5 is 2%.

In other words, the boundaries 26a-26c depend on true SOC of the secondary battery 5 at the time point at which the voltage measurement value Eo has reached the discharge final voltage. This will be described in detail below.

The voltage measurement value Eo (CCV of the secondary battery 5) is a value derived by subtracting overvoltage from an open circuit voltage (OCV) of the secondary battery 5. The overvoltage value depends on internal resistance of the secondary battery 5. The internal resistance of the secondary battery 5 increases as the temperature of the secondary battery 5 decreases. The overvoltage of the secondary battery 5 increases as an absolute value of the current flowing through the secondary battery 5 increases.

During discharge of the secondary battery 5, the voltage measurement value Eo is smaller than the OCV of the secondary battery 5. Thus, even in the case where the voltage measurement value Eo has reached the discharge final voltage, there is a case in which the true SOC of the secondary battery 5 is greater than 0%.

The true SOC of the secondary battery 5 in the case where the voltage measurement value Eo has reached the discharge final voltage varies depending on the internal resistance of the secondary battery 5. In other words, the true SOC of the secondary battery 5 in the case where the voltage measurement value Eo has reached the discharge final voltage varies depending on the temperature of the secondary battery 5 and the current flowing through the secondary battery 5. Therefore, the boundaries 26a-26c can be determined by measuring, in advance, the operating point of the secondary battery 5 for each true SOC of the secondary battery 5 in the case where the voltage measurement value Eo has reached the discharge final voltage.

(Case in which the Voltage Measurement Value Eo has Reached the Upper Limit Value)

The region determiner 241 receives the determination result K from the voltage monitor 23. In a case where the determination result K indicates that the voltage measurement value Eo has reached the upper limit value (the charge upper limit voltage), the region determiner 241 determines, as the correction time point, the time point at which the voltage measurement value Eo has reached the upper limit value. The region determiner 241 identifies the current measurement value Ia and the temperature measurement value Ta obtained at the correction time point (the step S131 in FIG. 5).

Since the voltage measurement value Eo has reached the upper limit value (No in the step S132), the region determiner 241 reads out the correction region data 27 from the storage 25 (a step S134). The region determiner 241 identifies the operating point of the secondary battery 5 based on the current measurement value Ia and the temperature measurement value Ta at the correction time point (a step S135).

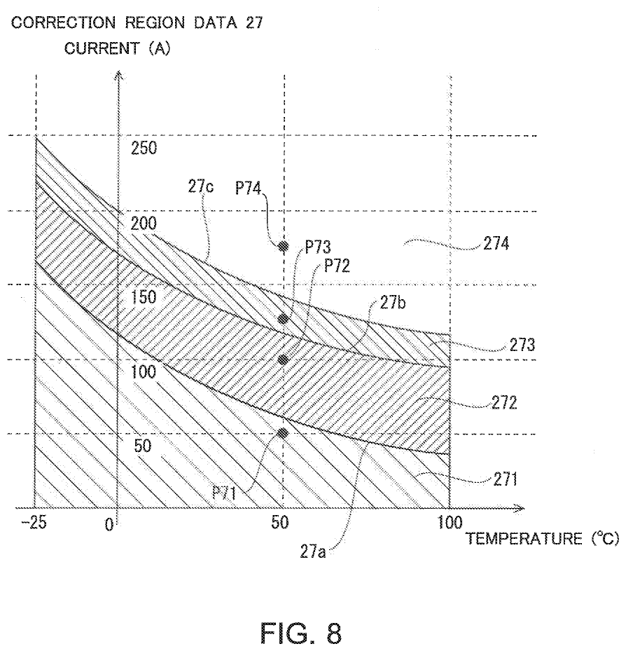

FIG. 8 illustrates an example of the correction region data 27 for the upper limit value. As shown in FIG. 8, the correction region data 27 includes the correction regions 271-273 and the non-correction region 274. The correction regions 271-273 and the non-correction region 274 are defined by a 2-dimensional coordinate having temperature of the secondary battery 5 on the horizontal axis and current flowing through the secondary battery 5 on the vertical axis.

The correction regions 271-273 are defined in a range of the temperature of the secondary battery 5 from −25 degrees Celsius to 100 degrees Celsius, and in a range of the current of the secondary battery 5 from 0 A to 250 A. The correction region 271 is a region in which the true SOC of the secondary battery 5 is 100% when the voltage measurement value Eo has reached the discharge final voltage. The correction region 272 indicates that the true SOC of the secondary battery 5 is 99% when the voltage measurement value Eo has reached the discharge final voltage. The correction region 273 indicates that the true SOC of the secondary battery 5 is 98% when the voltage measurement value Eo has reached the discharge final voltage. The non-correction region 274 is a region outside the correction regions 271-273 in the 2-dimensional coordinate shown in FIG. 6.

Points P71 to P74 shown in FIG. 8 are examples of the operating point of the secondary battery 5, and those points are not included in the correction region data 27. In a case where the temperature measurement value Ta is 50 degrees Celsius and the current measurement value Ia is 50 A, the operating point of the secondary battery 5 is the point P71. In a case where the temperature measurement value Ta is 50 degrees Celsius and the current measurement value Ia is 100 A, the operating point of the secondary battery 5 is the point P72. In a case where the temperature measurement value Ta is 50 degrees Celsius and the current measurement value Ia is 125 A, the operating point of the secondary battery 5 is the point P73. In a case where the temperature measurement value Ta is 50 degrees Celsius and the current measurement value Ia is 175 A, the operating point of the secondary battery 5 is the point P74.

As shown in FIG. 7, in the correction value table 28, each of the correction regions 271-273 is associated with a correction value. The correction value corresponding to the correction region 271 is 100%. The correction value corresponding to the correction region 272 is 99%. The correction value corresponding to the correction region 273 is 98%.

Correction of the SOC estimation value Fe when the voltage measurement value Eo has reached the upper limit value will be described below. For example, in a case where the operating point of the secondary battery 5 is at the point P72, the region determiner 241 determines that the operating point of the secondary battery 5 is within the correction region 272 (Yes in the step S136). The estimation value corrector 242 corrects the SOC estimation value Fe by use of the correction value corresponding to the correction region 272 (the step S137). The SOC estimation value Fe is set to 99%.

In a case where the operating point of the secondary battery 5 is the point P74, the region determiner 241 determines that the operating point of the secondary battery 5 is within the non-correction region 274 (No in the step S136). The estimation value corrector 242 determines not to correct the SOC estimation value Fe (the step S138).

A method of determining the correction regions 271-273 will be described below. As shown in FIG. 8, the correction region 271 is a region between a boundary 27a and the horizontal axis. The correction region 272 is a region between the boundary 27a and a boundary 27b. The correction region 273 is a region between the boundary 27b and the boundary 27c.

The boundaries 27a-27c are curves that show the relationship between the temperature of the secondary battery 5 and the ampacity current of the secondary battery 5, and those curves are plotted based on the true SOC of the secondary battery 5 when the voltage measurement value Eo has reached the charge upper limit voltage.

The boundary 27a shows a relationship between the temperature of the secondary battery 5 and the ampacity current of the secondary battery 5 when the true SOC of the secondary battery 5 is 100%. The boundary 27b shows a relationship between the temperature of the secondary battery 5 and the ampacity current of the secondary battery 5 when the true SOC of the secondary battery 5 is 99%. The boundary 27c shows a relationship between the temperature of the secondary battery 5 and the ampacity current of the secondary battery 5 when the true SOC of the secondary battery 5 is 98%.

While the secondary battery 5 is being charged, the voltage measurement value Eo is greater than OCV of the secondary battery 5. Reaching the charge upper limit voltage of the voltage measurement value Eo does not mean that OCV of the secondary battery 5 has reached the charge upper limit voltage. In other words, even if the voltage measurement value Eo has reached the charge upper limit voltage, there is a case in which the true SOC of the secondary battery 5 is smaller than 100%.

The true SOC of the secondary battery 5 in the case where the voltage measurement value Eo has reached the charge upper limit voltage varies depending on the temperature of the secondary battery 5 and the current flowing through the secondary battery 5, similarly to the method of determining the correction regions 261-263. Therefore, the operating point of the secondary battery 5 in the case where the voltage measurement value Eo has reached the charge upper limit voltage is measured in advance for each true SOC of the secondary battery 5 so that the boundaries 27a-27c can be determined.

As described above, the SOC estimation apparatus 20 of the embodiment determines, as the correction time point, the time point at which the voltage measurement value Eo has reached the lower limit value or the upper limit value in the case where the voltage measurement value Eo has reached the lower limit value or the upper limit value. The SOC estimation apparatus 20 of the embodiment identifies the operating point of the secondary battery 5 based on the current measurement value Ia and the temperature measurement value Ta obtained at the correction time point. The SOC estimation apparatus 20 corrects the SOC estimation value Fe of the secondary battery 5 based on the identified operating point. Since the SOC estimation apparatus 20 corrects the SOC estimation value Fe based on the current measurement value Ia and the temperature measurement value Ta obtained at the correction time point, even if charge or discharge of the secondary battery 5 continues, accuracy of the SOC estimation value of the secondary battery 5 can be improved.

When the CCV of the secondary battery 5 has reached the lower limit value or the upper limit value, the SOC estimation apparatus 20 corrects the SOC estimation value Fe. Since the SOC estimation apparatus 20 corrects the SOC estimation value even during the charge or discharge of the secondary battery 5, accuracy of the SOC estimation value during the charge or discharge of the secondary battery 5 can be improved.

In the case where the operating point of the secondary battery 5 is within the non-correction region, the SOC estimation apparatus 20 does not correct the SOC estimation value Fe. In the non-correction region, the SOC estimation value Fe of the secondary battery 5 is not corrected based on the temperature and the current of the secondary battery 5. In a case where correction of the SOC estimation value is not appropriate, the SOC estimation apparatus 20 does not correct the SOC estimation value. Thus, the SOC estimation apparatus 20 prevents accuracy of the SOC estimation value from decreasing, by correcting the SOC estimation value.

Each of the correction region data 26 and 27 includes the plurality of the correction regions. The SOC estimation apparatus 20 has greater opportunity to correct the SOC estimation value as compared to a case in which number of the correction region is one. Thus, the SOC estimation apparatus 20 can further improve the accuracy of the SOC estimation value.

[Modifications]

The foregoing embodiment describes the example in which the voltage monitor 23 determines whether or not the voltage measurement value Eo has reached the upper limit value or the lower limit value. However, the SOC estimation apparatus 20 is not limited to this. The voltage monitor 23 may use at least one of the upper limit value and the lower limit value.

The foregoing embodiment describes the example in which the SOC estimation apparatus 20 estimates the SOC of the entire secondary battery 5. However, a configuration of the SOC estimation apparatus 20 is not limited to this. The SOC estimation apparatus 20 may control the SOC of the secondary battery in a unit of cell or stack. In a case where the SOC estimation apparatus 20 controls the SOC in the unit of cell, the voltage sensor 7 derives the voltage measurement value Eo for each cell of the secondary battery 5. The SOC estimation apparatus 20 corrects the SOC of a cell of which a voltage measurement value Eo had reached the upper limit value or the lower limit value, amongst the cells of the secondary battery 5. This is applied to a case in which the SOC estimation apparatus 20 controls the SOC in the unit of stack.

The foregoing embodiment describes the example in which the region determiner 241 determines the operating point of the secondary battery 5 based on the current measurement value Ia and the temperature measurement value Ta obtained at the time point closest to the correction time point. However, the configuration is not limited to this. The region determiner 241 may set a target time period including the correction time point, and calculate a representative value of the current measurement value Io obtained by the measurement value obtaining part 21 during the target time period. In this case, the calculated representative value of the current measurement value Io is used as the current measurement value Ia at the correction time point. The representative value is, for example, an average value, an intermediate value, etc. This can be applied to the temperature measurement value Ta. Moreover, the target time period may include a time period later than the correction time point.

The foregoing embodiment describes the example in which the correction region data 26 and 27 individually have the three correction regions. However, number of the correction regions is not limited to three. Each of the correction region data 26 and 27 may have at least one correction region. In a case where the number of the correction regions is one, it is recommended that each of the correction region data 26 and 27 should include a correction region for a correction value being 0%. Each of the correction region data 26 and 27 may have four or more correction regions.

The foregoing embodiment describes the example in which the estimation value corrector 242 replaces the SOC estimation value Fe with the correction value. However, the configuration is not limited to this. The estimation value corrector 242 may add a correction value to the SOC estimation value Fe, or may multiply the SOC estimation value Fe by a correction value. The estimation value corrector 242 uses a correction value to correct the SOC estimation value Fe.

The foregoing embodiment describes the example in which the lower limit value is the discharge final voltage, and the upper limit value is the charge upper limit voltage. However, the configuration is not limited to this. For example, the lower limited value may be a CCV of the secondary battery 5 in a case where the SOC of the secondary battery 5 is 10%. The upper limit value may be a CCV of the secondary battery 5 in the case where the SOC of the secondary battery 5 is 90%. In this case, the lower and upper limit values are set based on a SOC-CCV characteristic. In other words, the voltage monitor 23 may determine whether or not the voltage measurement value Eo has reached the predetermined voltage threshold.

The foregoing embodiment describes the example in which the corrector 24 includes the region determiner 241 and the estimation value corrector 242. However, the configuration is not limited to this. If the corrector 24 corrects the SOC estimation value Fe based on the current measurement value Ia and the temperature measurement value Ta obtained at the correction time point, a method of correcting the SOC estimation value Fe is not limited to this.

In the foregoing embodiment, each functional block of the SOC estimation apparatus 20 may be a chip as a semiconductor apparatus, such as an LSI, or a chip that includes a portion or an entire of the functional block. Here, the chip is described as LSI, but the chip may be called IC, a system LSI, a super LSI, an ultra LSI, etc., depending on a degree of the integration.

Moreover, a method of integrating the circuit is not limited to LSI. The integration may be realized by a specific circuit or a general-purpose processor. It may be possible to use a field programmable gate array (FPGA) that is programmable after production of LSI or a reconfigurable processor of which connection or setting of a circuit cell in the LSI can be reconfigured.

A partial process or an entire process of a functional block of the SOC estimation apparatus 20 may be realized by a program. In the foregoing embodiment, the partial process or the entire process of a functional block of the SOC estimation apparatus 20, is performed by a central processing unit (CPU) in a computer. A program for each process is stored in a storage, such as a hard disk and a ROM, and the program is executed in the ROM or in a RAM after being read from the ROM.

Moreover, each process in the foregoing embodiment may be performed by a hardware or software (operating system (OS), middleware, or including combination with a predetermined library). Further, the process may be performed by collaboration of the software and the hardware.

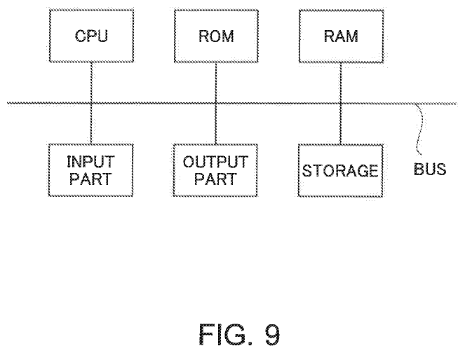

For example, in a case where a functional block of the foregoing embodiment (including modifications) is performed by software, each function may be executed by software by use of a hardware configuration (e.g., hardware configuration in which a CPU, a ROM, a RAM, input/output parts, etc. are connected via bus) shown in FIG. 9.

Further, an execution order of the processes in the foregoing embodiment are not necessarily limited to the description in the embodiment, and may be changed without departing from the purpose of the invention.

The scope of this invention includes a computer program that causes a computer to execute the foregoing method, and a computer-readable memory in which the computer program is stored. Here, some among the computer-readable memories are flexible disk, hard disk, CD-ROM, MO, DVD, DVD-ROM, DVD-RAM, large storage DVD, next generation DVD, semiconductor memory, etc.

The computer program is not limited to a program that is stored in the memory, but may be a program that is transmitted, for example, via an electrical communication line, wireless communication, wired communication, and a network, typically the internet.

The embodiment and modifications of the invention are described above. However, the foregoing embodiment and modifications are only examples to implement the invention. Thus, the invention is not limited to the foregoing embodiment and modifications. It is possible to appropriately modify the embodiment of the invention, not departing from the scope of the invention.

While the invention has been shown and described in detail, the foregoing description is in all aspects illustrative and not restrictive. It is therefore understood that numerous other modifications and variations can be devised without departing from the scope of the invention.

What is claimed is:

1. A state of charge estimation apparatus that estimates a state of charge of a secondary battery, the state of charge estimation apparatus comprising a processor and associated memory configured to:
obtain a voltage measurement value, a current measurement value, and a temperature measurement value of the second battery;
calculate a state of charge estimation value of the secondary battery based on the current measurement value;
determine whether or not the voltage measurement value of the secondary battery has reached a predetermined voltage threshold during charge or discharge of the secondary battery; and
in a case where the voltage measurement value of the secondary battery is determined to have reached the voltage threshold, correct the state of charge estimation value based on the current measurement value and the temperature measurement value that are obtained at a correction time point at which the voltage measurement value of the secondary battery has reached the voltage threshold.

2. The state of charge estimation apparatus according to claim 1, wherein
the voltage threshold is a discharge final voltage of the secondary battery or a charge upper limit voltage of the secondary battery.

3. The state of charge estimation apparatus according to claim 1, wherein
the processor is further configured to:
determine whether or not an operating point of the secondary battery is within a first region that is defined based on current flowing through the secondary battery and temperature of the secondary battery, the operating point of the secondary battery being defined by the current measurement value and the temperature measurement value that are obtained at the correction time point; and
in a case where the operating point is determined to be within the first region, correct the state of charge estimation value by use of a correction value corresponding to the first region.

4. The state of charge estimation apparatus according to claim 3, wherein
the processor is further configured to:
determine whether or not the operating point of the secondary battery is within a second region that is different from the first region, the second region being preset based on the current flowing through the secondary battery and the temperature of the second battery, and
in a case where the operating point is within the second region, correct the state of charge estimation value of the secondary battery by use of a correction value corresponding to the second region.

5. A state of charge estimation method of estimating a state of charge of a secondary battery, the method comprising the steps of:
obtaining a voltage measurement value, a current measurement value, and a temperature measurement value of the second battery;
calculating a state of charge estimation value of the secondary battery based on the current measurement value;
determining whether or not the voltage measurement value of the secondary battery has reached a predetermined voltage threshold during charge or discharge of the secondary battery; and
in a case where the voltage measurement value of the secondary battery is determined to have reached the voltage threshold, correcting the state of charge estimation value based on the current measurement value and the temperature measurement value that are obtained at a correction time point at which the voltage measurement value of the secondary battery has reached the voltage threshold.

6. A non-transitory computer-readable medium storing instructions that, when executed by a computer, cause the computer to:
obtain a voltage measurement value, a current measurement value, and a temperature measurement value of the second battery;
calculate a state of charge estimation value of the secondary battery based on the current measurement value;
determine whether or not the voltage measurement value of the secondary battery has reached a predetermined voltage threshold during charge or discharge of the secondary battery; and
in a case where the voltage measurement value of the secondary battery is determined to have reached the voltage threshold, correcting the state of charge estimation value based on the current measurement value and the temperature measurement value that are obtained at a correction time point at which the voltage measurement value of the secondary battery has reached the voltage threshold.
